(19) United States
(12) Patent Application Publication
(10) Pub. No.: US 2004/0163597 A1
(43) Pub. Date: Aug. 26, 2004

(54) Apparatus for fabricating semiconductor devices, heating arrangement, shower head arrangement, method of reducing thermal disturbance during fabrication of a semiconductor device, and method of exchanging heat during fabrication of a semiconductor device

(76) Inventors: Moon-Sook Lee, Seoul (KR); Byoung-Jae Bae, Suwon-si (KR)

Correspondence Address: HARNESS, DICKEY & PIERCE, P.L.C., P.O. BOX 8910, RESTON, VA, 20195, US

(21) Appl. No.: 10/784,772

(22) Filed: Feb. 24, 2004

(30) Foreign Application Priority Data
Feb. 25, 2003 (KR) 2003-11778
Jul. 25, 2003 (KR) 2003-51434

(51) Int. Cl. H01L 21/44; C23C 16/00

(52) U.S. Cl. 118/724; 438/681

(57) ABSTRACT

An apparatus for fabricating a semiconductor device in which a substance is deposited on a semiconductor wafer. The apparatus includes a heating arrangement and/or a shower head arrangement. The shower head arrangement supplies at least two source gases to the apparatus. The heating arrangement heats at least one of the source gases supplied to a process chamber of the apparatus. The heating arrangement may include a heat pipe including at least one part. A method of reducing thermal disturbance during fabrication of a semiconductor device using the heating arrangement and a method of exchanging heat during fabrication of the semiconductor device using the heating arrangement.

### BACKGROUND OF THE INVENTION

The application claims the benefit of the priority of Korean Patent Application No. 2003-11778, filed on Feb. 25, 2003 and Korean Patent Application No. 2003-51434, filed on Jul. 25, 2003, in the Korean Intellectual Property Office, the entire contents of both of which are hereby incorporated by reference.

### FIELD OF THE INVENTION

The present invention relates to an apparatus for fabricating a semiconductor device, a heating arrangement, a shower head arrangement, a method of reducing thermal disturbance during fabrication of a semiconductor device, and a method of exchanging heat during fabrication of a semiconductor device.

### DESCRIPTION OF THE RELATED ART

Several processes, such as an ion implanting process, a deposition process, a photolithography process and an etching process may be used to fabricate semiconductor devices. Among these processes, the deposition process is used for forming a film on a wafer and may be further classified into a chemical vapor deposition method and a physical vapor deposition method. Recently, a metal organic chemical vapor deposition (MOCVD) process has been widely used in which a volatile metal organic compound is used as a precursor to deposit a film, such as a high dielectric thin film, a ferro-dielectric thin film, a superconductive thin film, or a metal oxide thin film usable as an electrode on a wafer.

FIG. 1 is a schematic sectional view illustrating a conventional MOCVD apparatus. Referring to FIG. 1, the MOCVD apparatus includes a susceptor 160 (which itself may include a surrounding and/or embedded heater which is not shown) and a showerhead 140 disposed to face each other within a process chamber 120. A semiconductor substrate (W) such as a wafer is placed on the susceptor 160. The showerhead 140 is connected to a pipe 182 for supplying a first source gas as a metal organic precursor, and a pipe 184 for supplying a second source gas such as oxygen, nitrogen, ammonia, etc. Generally, the first source gas is supplied to the showerhead 140 in a heated state so as not to allow re-liquefaction or heat-decomposition, and the second source gas is supplied to the showerhead 140 at room temperature.

The wafer (W) may be heated to a process temperature of about 500° C. that is higher than a decomposition temperature of the source gases, and the first and second source gases are showered downwardly through a shower hole 142 of the showerhead 140 to be deposited on the wafer (W). In a conventional deposition method, the first source gas, a purge gas and the second source gas may be sequentially supplied to deposit a certain quality film on the wafer (W).

However, the conventional MOCVD apparatus may have the following drawbacks. Since the source gas is deposited when the wafer (W) is heated at a temperature above 500° C., a heater of the susceptor 160 should be elevated at a temperature above about 600° C. Accordingly, an outer wall of the process chamber 120 and the showerhead 140 may be heated at a higher temperature than the decomposition temperature of the source gas such that the source gases may be previously decomposed and deposited on the outer wall of the process chamber 120 and the showerhead 140. Additionally, equipment may be damaged and worker's safety may be threatened since the outer wall of the process chamber 120 is heated at a high temperature. Further, a thermal disturbance may be generated and the reaction may be deteriorated due to a temperature difference between the first and second source gases, since the first source gas is supplied to the showerhead 140 in a heated state while the second source gas is supplied to the showerhead 140 at room temperature.

### SUMMARY OF THE INVENTION

Exemplary embodiments of the present invention are directed to an apparatus for fabricating a semiconductor device, a heating arrangement, a shower head arrangement, a method of reducing thermal disturbance during fabrication of a semiconductor device, and a method of exchanging heat during fabrication of a semiconductor device that may substantially obviate one or more problems due to limitations and disadvantages of the conventional art.

Exemplary embodiments of the present invention provide an apparatus for fabricating a semiconductor device, a heating arrangement, a shower head arrangement, a method of reducing thermal disturbance during fabrication of a semiconductor device, and a method of exchanging heat during fabrication of a semiconductor device for allowing a source gas to be satisfactorily deposited on a wafer.

In an exemplary embodiment, an apparatus for fabricating a semiconductor device includes a process chamber, a susceptor disposed within the process chamber, the susceptor being heated to a high temperature while a process is performed, a shower part facing the susceptor within the process chamber, a first supply pipe for supplying a first source gas to the process chamber, and a heating device for heating the first source gas. In an exemplary embodiment, the heating device is a heat pipe which has one end connected with the first supply pipe and the other end connected with the shower part. In an exemplary embodiment, the heat pipe passes around the high temperature susceptor. In another exemplary embodiment, the heat pipe has a first heat part being coil-shaped to surround a circumference of the susceptor.

In an exemplary embodiment, the heat pipe has a first heat part which is formed ranging from a lower portion of a sidewall of the process chamber to an upper portion of the sidewall of the process chamber, and is inserted into an outer wall of the process chamber. In an exemplary embodiment, the heat pipe has a second heat part disposed in the lower wall of the process chamber and connected with the first supply pipe. In an exemplary embodiment, the second heat part is spiral-shaped to have a radius that gradually increase from a central portion of the lower wall of the process chamber to the outside portion on the same plane. In an exemplary embodiment, the heat pipe further includes a third heat part disposed at an upper portion within the process chamber and connected with the shower part. The third part is spiral-shaped to have a radius that gradually increases from a central portion of the upper wall of the process chamber to the outside portion on the same plane.

In another exemplary embodiment, the first heat part is disposed between the outer wall of the process chamber and the susceptor, and surrounds a circumference of the susceptor in a coiled shape. In another exemplary embodiment, a liner is disposed between the first heat part of the heat pipe and the susceptor to reduce the likelihood or prevent a process byproduct from being attached to the first supply pipe. According to an exemplary embodiment, the third heat part extends from the first heat part and surrounds the circumference of the shower part in a coiled shape.

In another exemplary embodiment, the apparatus for fabricating a semiconductor device is a metal organic chemical vapor deposition (MOCVD) apparatus and further includes a second supply pipe for supplying a second source gas to the shower part.

In another exemplary embodiment, the first source gas flows into the process chamber at room temperature, and the second source gas is a metal organic gas flowing into the process chamber in a heated state.

In another exemplary embodiment, the heating device may be a heater installed on the first supply pipe to thereby heat the first source gas.

In another exemplary embodiment, a heating arrangement for heating a source gas in an apparatus for fabricating a semiconductor device includes at least one heating device for heating at least one source gas input to the apparatus for fabricating the semiconductor device.

In another exemplary embodiment, a shower head arrangement for supplying at least two source gases to an apparatus for fabricating a semiconductor device includes at least one inlet part for receiving the at least two source gases, the at least two source gases being heating above room temperature and at least one shower plate for delivering the at least two source gases to a process chamber of the apparatus for fabricating a semiconductor device.

In another exemplary embodiment, a shower head arrangement for supplying at least two source gases to an apparatus for fabricating a semiconductor device includes at least two inlet parts, each for receiving one of the at least two source gases and at least two shower plates, each for delivering one of the at least two source gases to a process chamber of the apparatus for fabricating a semiconductor device.

In another exemplary embodiment, a method of reducing thermal disturbance during fabrication of a semiconductor device includes heating a first source gas to be supplied to a process chamber above room temperature and heating all other source gases to be supplied to the process chamber above room temperature.

In another exemplary embodiment, a method of exchanging heat during fabrication of a semiconductor device includes heating a source gas to be supplied to a process chamber above room temperature using a heat source internal to the process chamber.

It is to be understood that both the foregoing general description and the following detailed description of the present invention are exemplary and explanatory to provide further explanation of the invention as claimed.

### BRIEF DESCRIPTION OF THE DRAWINGS

Exemplary embodiments of the present invention will be readily apparent to those of ordinary skill in the art upon review of the detailed description that follows when taken in conjunction with the accompanying drawings, in which like reference numerals denote like parts, and in which:

FIG. 1 is a sectional view illustrating a conventional MOCVD (metal organic chemical vapor deposition) apparatus;

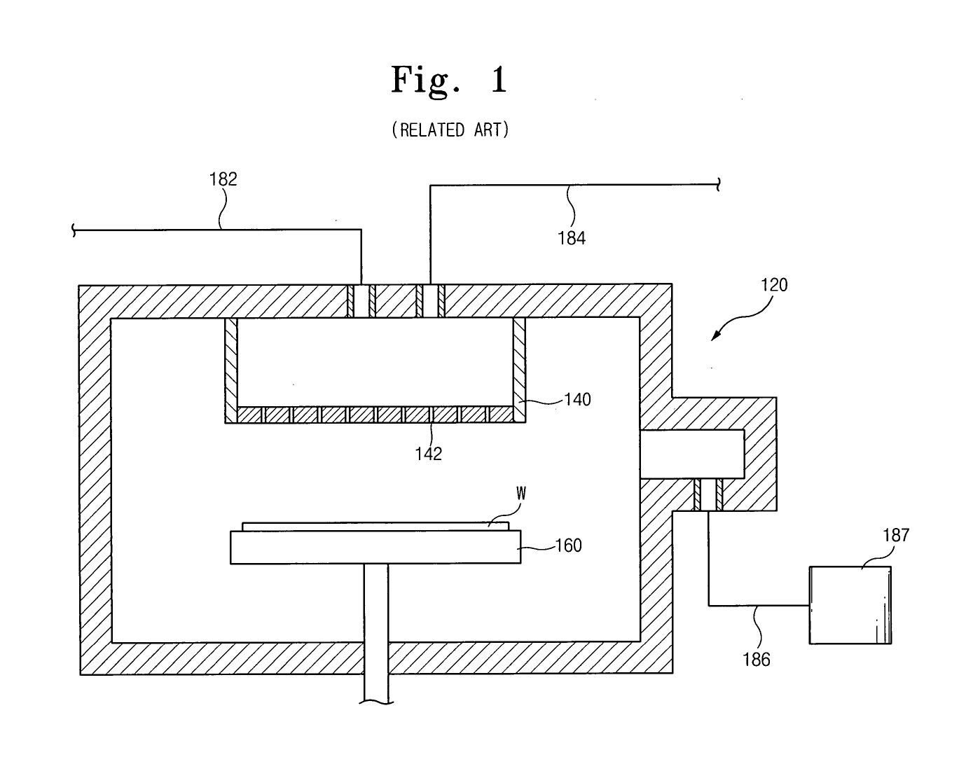

FIG. 2 is a sectional view illustrating a MOCVD apparatus in accordance with a first exemplary embodiment of the present invention;

FIG. 3 is a sectional view illustrating a modified example of a MOCVD apparatus of FIG. 2;

FIG. 4 is a sectional view illustrating a MOCVD apparatus in accordance with a second exemplary embodiment of the present invention;

FIG. 5 is a perspective view illustrating a heat pipe and a liner of FIG. 4;

FIG. 6 is a sectional view illustrating a modified example of a MOCVD apparatus of FIG. 4;

FIG. 7 is a perspective view illustrating a heat pipe and a liner of FIG. 6; and

FIG. 8 is a sectional view illustrating a MOCVD apparatus in accordance with a third exemplary embodiment of the present invention.

### DETAILED DESCRIPTION OF EXEMPLARY EMBODIMENTS OF THE INVENTION

Reference will now be made in detail to the exemplary embodiments of the present invention, which are illustrated in the accompanying drawings. It should be recognized that the present invention is not limited by any of the details of the exemplary embodiments explained herein, but embodied in different forms. The exemplary embodiments of the present invention are provided merely to thoroughly completely convey ideas of the present invention to those skilled in the art that the present invention pertains to.

In the following exemplary embodiments, a metal organic chemical vapor deposition (MOCVD) apparatus is exemplified for description, but the apparatus of the present invention may be used in any other type of apparatus for fabricating a semiconductor device in which a film is formed on a wafer at higher than room temperature.

Further, the inventive apparatus may be used in a deposition method for simultaneously supplying source gases into a process chamber (such as a chemical vapor deposition method), or a deposition method for sequentially supplying the source gases into the process chamber ((such as an atomic layer deposition method).

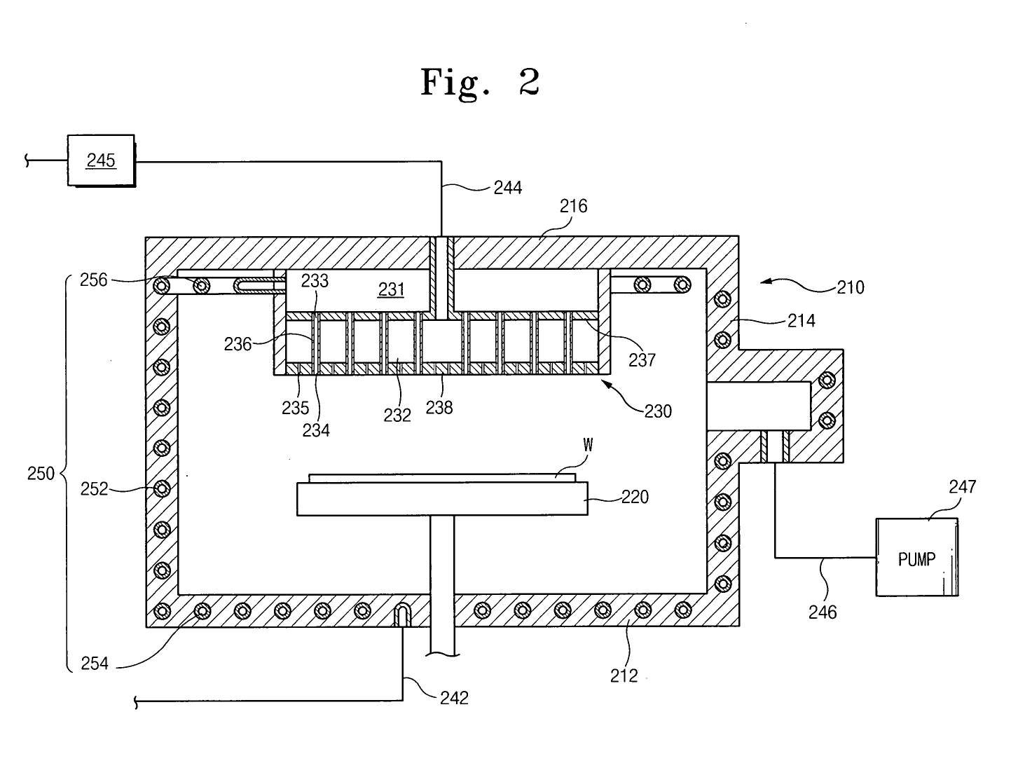

FIG. 2 is a schematic sectional view illustrating a MOCVD apparatus in accordance with a first exemplary embodiment of the present invention.

Referring to FIG. 2, the MOCVD apparatus includes a process chamber 210, a susceptor 220, a showerhead 230, a first supply pipe 242, a second supply pipe 244, and a heating device 250.

The susceptor 220 on which the wafer (W) is mounted may be provided in a lower portion of the process chamber 210. In order to heat the wafer (W) at a high temperature, to maintain an inner space of the process chamber 210 at a temperature above a decomposition temperature of the source gases, and to satisfactorily deposit the source gases on the wafer (W), a heater (not shown) may installed around and/or inside the susceptor 220. Generally, the temperature of the susceptor 220 may be elevated to a temperature above 600° C. by the heater since the wafer (W) should be heated at a temperature above 500° C.

A shower part 230, such as a showerhead, may be provided in an upper portion of the process chamber 210 to face the susceptor 220. The shower part 230 showers the source gases downwardly into the process chamber 210, and is coupled to an upper surface of the process chamber 210.

A discharge line 246 is formed at one side surface or a bottom surface of the process chamber 210 to maintain the internal section of the process chamber 210 at a desired pressure and to discharge remnants remaining after deposition. The discharge line 246 may have a pump 247 connected thereto.

The shower part 230 may include a first inlet part 231 disposed at an upper portion and a second inlet part 232 disposed at a lower portion. A first shower plate 237 may be disposed between the first inlet part 231 and the second inlet part 232 to separate the first inlet part 231 and the second inlet part 232 from each other, and a second shower plate 238 may be formed below the second inlet part 232. The first shower plate 237 may have a plurality of first holes 233. The second shower plate 238 may have a plurality of second holes 234 at corresponding positions to the plurality of first holes 233, and a plurality of third holes 235 between the plurality of second holes 234. Shower pipes 236 may be inserted between the plurality of first holes 233 and the plurality of second holes 234.

The first inlet part 231 may correspond to a portion through which a first source gas is introduced, and the first source gas may be in a gaseous state at a room temperature. When depositing an oxide on the wafer (W), the first source gas may be oxygen (O₂) gas or other oxygen-based gas. When depositing a nitride on the wafer (W), the first source gas may be nitrogen (N₂) gas, ammonia (NH₃) gas or other nitrogen-based gas. The second inlet part 232 corresponds to a portion through which a second source gas is introduced. The second source gas may be a substance having a low steam pressure and existing in liquid/solid states at a room temperature, and may be a metal organic precursor gas supplied to the shower part 230 in an appropriately heated state.

The first source gas may be supplied from a first source gas supply source (not shown) to the process chamber 210 at room temperature through the first supply pipe 242. The first source gas may be heated to a desired temperature by the heating device 250 and is then supplied to the first inlet part 231. The second source gas may be supplied from a second source gas supply source (not shown) to the second inlet part 232 through the second supply pipe 244 in a heated state so as not to allow re-liquefaction or heat-decomposition. The supply source of the second source gas may include a liquid source substance-supplying part (not shown) and a liquid source substance vaporizing part 245. The first supply pipe 242 may be connected with one end of the heating device 250 disposed in the bottom wall 212 of the process chamber 210, and the second supply pipe 244 may be connected with the second inlet part 232 of the shower part 230 through the upper wall 216 of the process chamber 210. However, the heating device 250 may also be connected with the second inlet part 232, and the second supply pipe 244 may also be connected with the first inlet part 231.

In operation, the first source gas is heated by the heating device 250. In an exemplary embodiment, the heating device 250 may be a heat pipe. The heat pipe 250 guides the first source gas introduced through the first supply pipe 242 to the first inlet part 231. The heat pipe 250 may be arranged to pass around the high temperature susceptor 220 such that the first source gas flowing through the heat pipe 250 is heated at a desired temperature. In an exemplary embodiment, the heat pipe 250 may include a first heat part 252, a second heat part 254 and a third heat part 256. The first heat part 252 and the second heat part 254 allow the first source gas flowing therethrough to be heated at a desired temperature by using heat radiated from the susceptor 220. In an exemplary embodiment, the first heat part 252 may be inserted or embedded in a sidewall 214 of the process chamber 210, and may be helical or coil-shaped (a three-dimensional shape) ranging from a lower portion to an upper portion of the sidewall 214. The second heat part 254 may extend from one end of the first heat part 252 and be connected with the first supply pipe 242. The second heat part 254 may be inserted into the lower wall 212 of the process chamber 210, and may be spiral-shaped (a two-dimensional shape) to have a radius that decreases gradually from an edge portion to a central portion of the lower wall 212. The third heat part 256 may heat the first source gas flowing through the heat pipe 250 by using heat from the shower part 230, or cools the shower part 230 at a desired temperature. The third heat part 256 may extend from one end of the second heat part 254 and may be spiral-shaped (a two-dimensional shape) to have a radius that decreases gradually from the outside of the shower part 230. One end of the third heat part 256 may be connected with the first inlet part 231 of the shower part 230.

In operation of the MOCVD apparatus as constructed above, the susceptor 220 may be maintained at a temperature above 600° C. The first source gas may be supplied to the process chamber 210 through the first supply pipe 242 at a room temperature. The first source gas flows through the heat pipe 250 to the first inlet part 231 of the shower part 230 in a heated state caused by the heat radiated from the susceptor 220. Further, the second source gas as the precursor gas is heated at an appropriate temperature so as not to allow liquefaction or decomposition and is supplied into the second inlet part 232 of the shower part 230 through the second supply pipe 244. The first source gas supplied to the first inlet part 231 is showered downwardly through the shower pipe 236 of the shower part 230, and the second source gas supplied to the second inlet part 232 is showered downwardly through the plurality of third holes 235 of the second shower plate 238. The first and second source gases may be decomposed and recombined by a high temperature heater and then deposited on the wafer (W). The remnants remaining after deposition are discharged through the discharge pipe 246. A sensor (not shown) for sensing a temperature of the wafer (W) may be mounted on the susceptor 220. Accordingly, if the wafer (W) has a lower temperature than the process temperature for deposition due to heat exchange with the heat pipe 250, the wafer (W) may be heated to a higher temperature by the heater.

In the conventional MOCVD apparatus, the process chamber 210 and the shower part 230 are maintained to be at a temperature above the decomposition temperature of the source gas using the heat radiated from the heater. Accordingly, the source gases may be decomposed around an outer wall of the process chamber 210, and then deposited on the outer wall of the process chamber 210. However, exemplary embodiments of the present invention may solve the above-described drawback since the heat radiated from the susceptor 220 to the sidewall 214 of the process chamber 210 is used to heat the first source gas flowing through the first heat part 252 and the second heat part 254 to thereby maintain the outer wall of the process chamber 210 at a low temperature in comparison with the conventional art. Additionally, since the heat exchange is performed between the high temperature heated shower part 230 and the first source gas flowing third heat part 256, the possibility may be reduced that the source gas may be decomposed around the shower part 230 and then deposited on the shower part 230.

Further, in the conventional MOCVD apparatus, since the second source gas flows into the shower part 230 in a heated state, while the first source gas flows into the shower part 230 at a room temperature, a thermal disturbance may be generated due to a temperature difference between the source gases and the reaction may be adversely affected by the thermal disturbance. In the exemplary embodiments of the present invention, since the first source gas is supplied to the shower part 230 in a heated state by using the heat radiated from the susceptor 220, a temperature difference with the second source gas may be not as large and may not influence a reaction for forming a thin film.

Further, exemplary embodiments of the present invention may not need a separate heating device for heating the first source gas or a separate cooling device for cooling the outer wall of the process chamber 210 and the shower part 230. However, separate heating and/or cooling devices may be installed.

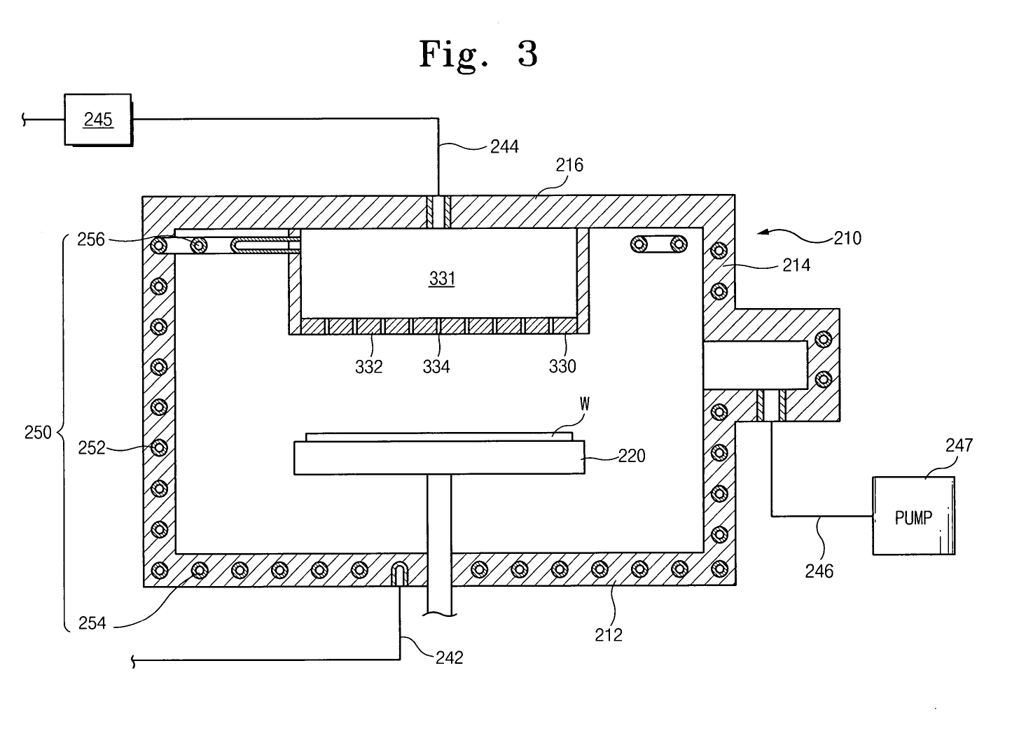

FIG. 3 illustrates a modified example of the MOCVD apparatus of FIG. 2. As shown in FIG. 3, a shower part 330 may include only one inlet part 331 and one shower plate 332. In this case, a first source gas and a second source gas are supplied to the same inlet part 331, and are showered downwardly through holes 334 of the shower plate 332 formed at a lower portion of the inlet part 331.

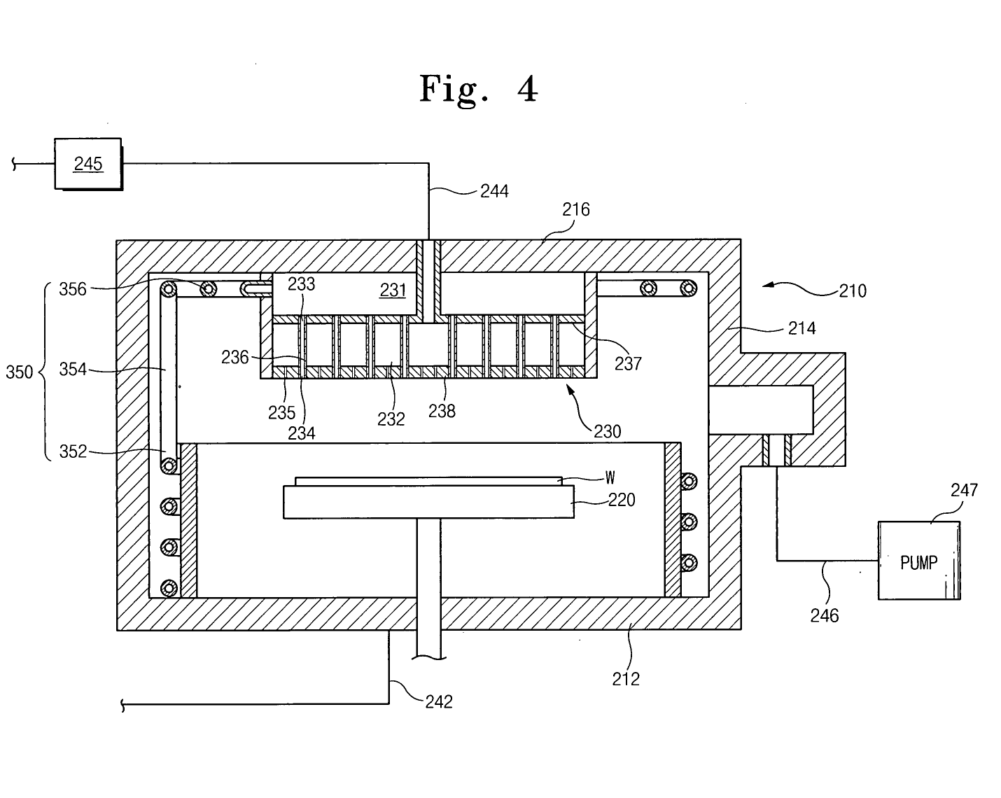

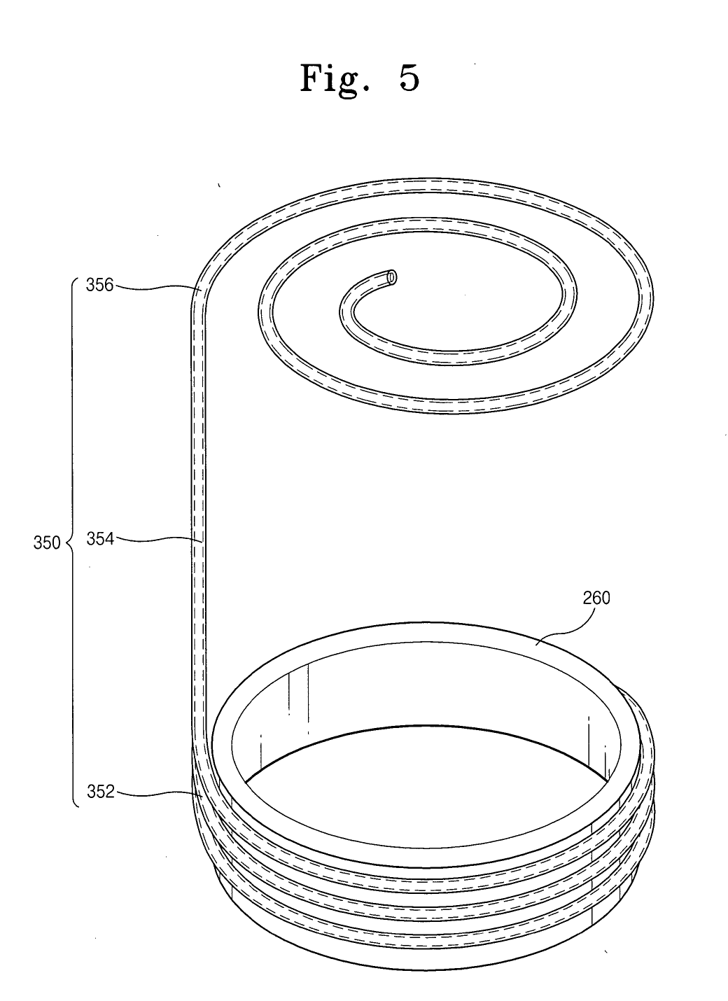

FIG. 4 is a sectional view illustrating a MOCVD apparatus in accordance with a second exemplary embodiment of the present invention, and FIG. 5 is a perspective view illustrating a heat pipe and a liner of FIG. 4.

Referring to FIG. 4, the MOCVD apparatus includes a process chamber 210, a shower part 230, a susceptor 220, a first supply pipe 242, a second supply pipe 244 and a heat pipe 350. Among them, a detailed description for the same elements as those of the previous exemplary embodiment is abbreviated, and the differently structured heat pipe 350 from the first exemplary embodiment will be described.

Referring to FIG. 5, the heat pipe 350 may include a first heat part 352, a transfer part 354, and a third heat part 356. The first heat part 352 is connected with the first supply pipe 242, and disposed between the sidewall 214 of the process chamber 210 and the susceptor 220. The first heat part 352 is installed to surround the susceptor 220 in a coiled shape (a three-dimensional shape) ranging from a bottom surface of the process chamber 210 to an upper surface of the susceptor 220. The transfer part 354 may extend from the first heat part 352, and may be linearly shaped at an upper portion of the process chamber 210. The third heat part 356 may extend from the transfer part 354 to exchange heat with the shower part 230, and may be connected with the first inlet part 231. As shown in FIG. 5, the third heat part 356 may be a helical-shape (a two-dimensional shape) and have a radius that decrease gradually from outside to inside in the same plane.

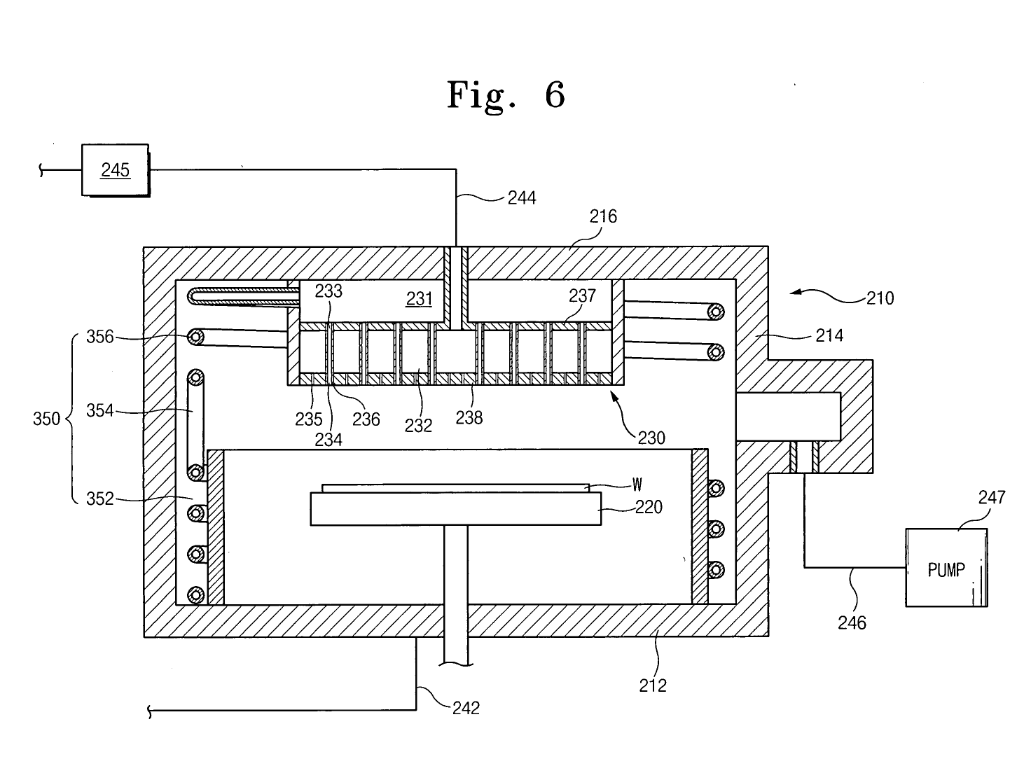

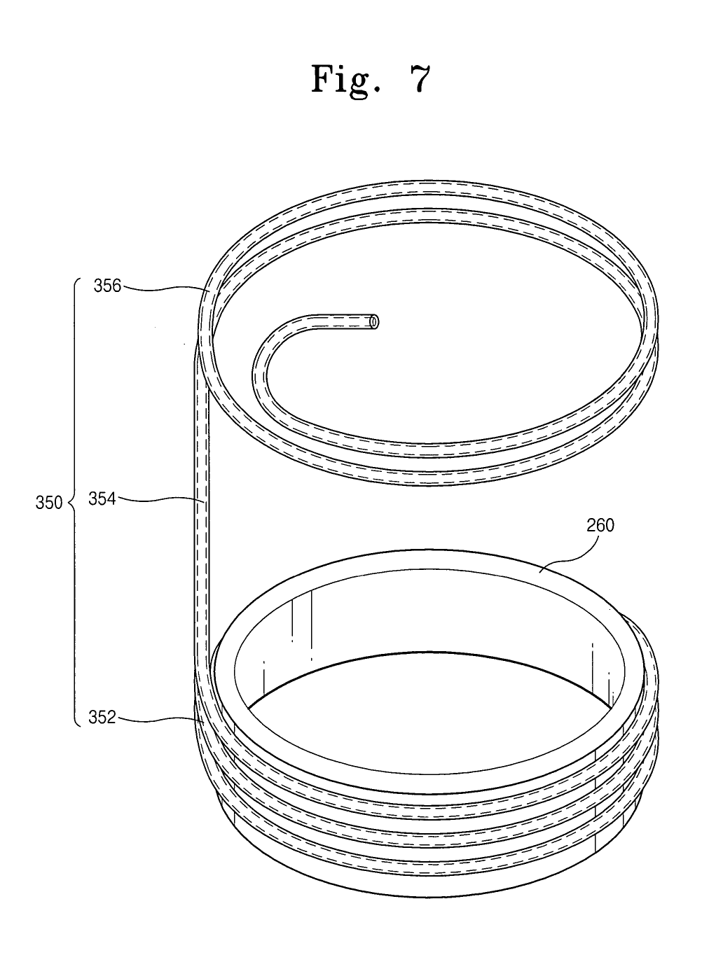

FIG. 6 is a sectional view illustrating a modified example of the MOCVD apparatus of FIG. 4, and FIG. 7 is a perspective view illustrating a heat pipe 250 and a liner of FIG. 6.

Referring to FIGS. 6 and 7, unlike that of FIG. 5, the third heat part 356 of the heat pipe 350 may be structured to surround the shower part 230 in a coiled shape (a three-dimensional shape) ranging from the second shower plate 238 to the first inlet part 231 of the shower part 230.

In another exemplary embodiment, the transfer part 354 may have a long or short length depending on its influence on the temperature of the first source gas, and the first heat part 352 may be extended to the shower part 230 in a coiled shape without the transfer part 354.

In another exemplary embodiment, since the heat pipe 350 is disposed inside an inner sidewall of the process chamber 210, the source gases may be deposited on the heat pipe 350. In this case, since the heat pipe 350 may have a short purge period, a liner (for example, cylindrical liner 260) may be installed inside of the first heat part 352 (and/or any other part) of the heat pipe 350. In an exemplary embodiment, the first heat part 352 may be formed close to the inner sidewall of the process chamber 210, and the liner 260 is disposed close to an inner side of the first heat part 352 of the heat pipe 350. However, the first heat part 352 of the heat pipe 350 may also be disposed to be at a distance from the inner sidewall of the process chamber 210, and the liner 260 may be respectively installed at the inner and outer sides of the first heat part 352.

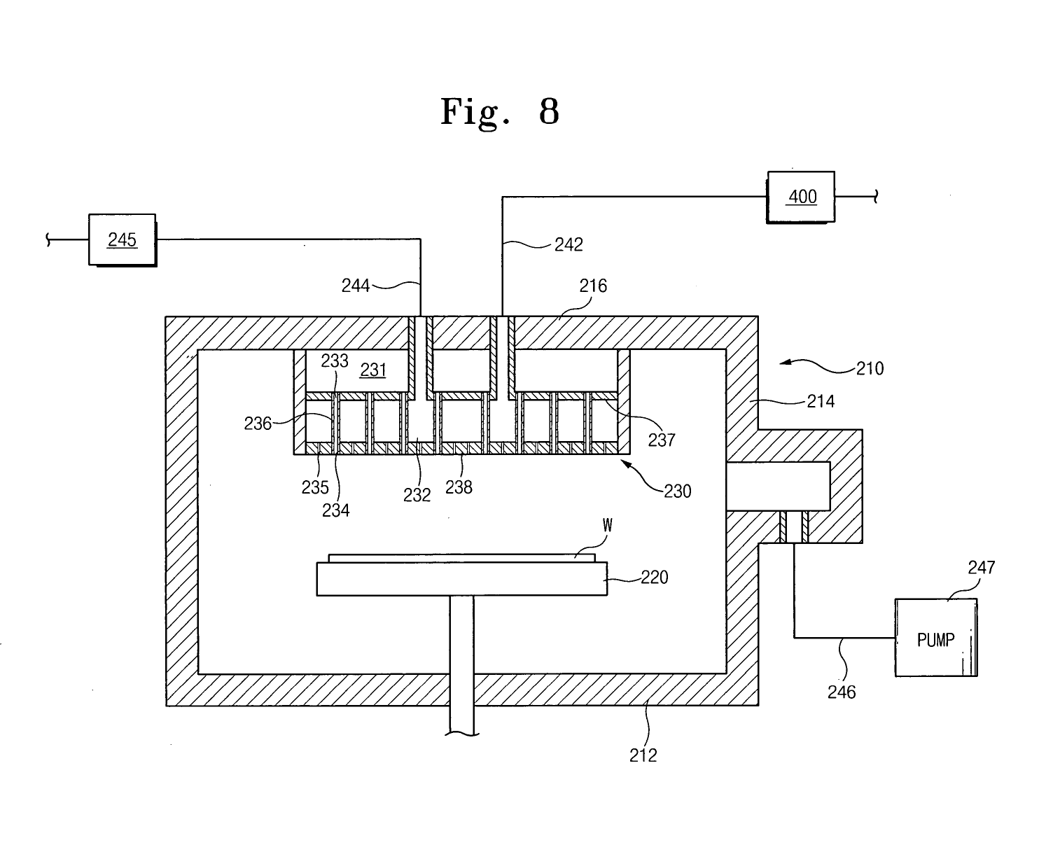

FIG. 8 is a sectional view illustrating a MOCVD apparatus in accordance with another exemplary embodiment of the present invention. Referring to FIG. 8, the MOCVD apparatus includes a process chamber 210, a shower part 230, a susceptor 220, a first supply pipe 242, a second supply pipe 244 and a heating device 400. Among them, a detailed description for the same elements as those of the previous exemplary embodiment is abbreviated, and the differently structured heating device from the previous exemplary embodiment will be described. In another exemplary embodiment, a heater 400 is used as the heating device. The heater 400 is installed on the first supply pipe to heat the first source gas. The first supply pipe is directly connected with the first inlet part 231 of the shower part 230. The construction of the MOCVD apparatus without a heat pipe is relatively simple.

A layer deposited by the apparatus according to exemplary embodiments of the present invention may be a ferroelectric layer. In case that a ferroelectric layer (e.g., Pb(Zr, Ti)O₃) is deposited, the second source gas may include a metal organic precursor gas and a carrier gas. The metal organic precursor gas may include lead (Pb) or compounds thereof, zirconium (Zr) or compounds thereof, and/or titanium (Ti) or compounds thereof. A liquid metal organic source is vaporized in the vaporizing part 245 and heated to a temperature so as not to allow reliquefication or heat decomposition. A carrier gas may serve as a carrier for supplying the metal organic precursor gas into the process chamber 210 and may be a non-reacting gas, such as nitrogen, helium or argon. The second source gas may be an oxygen gas as an oxidizer gas. The oxygen gas may be heated to a desired temperature before it flows into the first inlet part 231. As described above, a heater 400 may be installed on the first supply pipe 242 or the heat pipe 250 surrounding the susceptor 220 between the first supply pipe 242 and the first inlet part 231. The oxygen gas may be heated to a temperature of the metal organic precursor gas flowing into the process chamber 210. The oxidizer gas may include ozone (O₃), nitrogen oxide (N₂O), nitrogen dioxide (NO₂) or other oxygen-based gas.

As described above, the exemplary embodiments of the present invention contemplate a heat pipe including three parts, however, fewer or more parts could also be used as would be known to one of ordinary skill in the art.

As described above, the exemplary embodiments of the present invention contemplate a heat pipe part of linear, spiral, or helical shape, however, other two- and three-dimensional shapes could also be used as would be known to one of ordinary skill in the art.

As described above, the exemplary embodiments of the present invention provide apparatuses (for example, MOCVD apparatuses) having a simpler structure and/or easier apparatus maintenance without an additional heat device since the source gas such as oxygen and nitrogen is heated at a higher temperature using the heat radiated from the susceptor (which may also prevent or reduce a thermal eddy from occurring within the process chamber).

Further, exemplary embodiments of the present invention provide MOCVD apparatuses in that the process chamber and the shower part may be reduced or prevented from being deteriorated without using an additional cooling device, since the high temperature heat radiated from the susceptor is partially used to heat the source gas.

It will be obvious to those skilled in the art that various modifications may be made in the present invention. Such variations are not to be regarded as departure from the spirit and scope of the exemplary embodiments of the present invention, and all such modifications as would be obvious to one skilled in the art are intended to be included within the scope of the following claims.

What is claimed is:

1. An apparatus for fabricating a semiconductor device, comprising:
a process chamber;
a susceptor disposed within the process chamber;
a shower part disposed to face the susceptor within the process chamber;
a first supply pipe for supplying a first source gas to the process chamber; and
a heating device for heating the first source gas.

2. The apparatus of claim 1, wherein the heating device is a heat pipe that has one end connected with the first supply pipe, the other end connected with the shower part, the heat pipe passing around the susceptor.

3. The apparatus of claim 2, wherein the heat pipe has a first heat part coil-shaped to surround a circumference of the susceptor.

4. The apparatus of claim 3, wherein the first heat part is inside an outer wall of the process chamber.

5. The apparatus of claim 4, wherein the first heat part is formed ranging from a lower portion of a sidewall of the process chamber to an upper portion of the sidewall of the process chamber.

6. The apparatus of claim 3, wherein the heat pipe further has a second heat part disposed in a lower wall of the process chamber and connected with the first supply pipe, and being spiral-shaped to have a radius increasing from a central portion of the lower wall of the process chamber to an outside portion of the lower wall on the same plane.

7. The apparatus of claim 3, wherein the heat pipe further comprises a third heat part being disposed at an upper portion within the process chamber and connected with the shower part, and being spiral-shaped to have a radius increasing from a central portion of the upper wall of the process chamber to an outside portion of the upper wall on the same plane.

8. The apparatus of claim 3, wherein the first heat part is disposed between the outer wall of the process chamber and the susceptor.

9. The apparatus of claim 3, wherein the heat pipe further comprises a third heat part extending from the first heat part and surrounding a circumference of the shower part in a coiled shape.

10. The apparatus of claim 3, further comprising a liner disposed between the first heat part of the heat pipe and the susceptor.

11. The apparatus of claim 1, further comprising a second supply pipe for supplying a second source gas to the shower part.

12. The apparatus of claim 11, wherein the apparatus is a metal organic chemical vapor deposition (MOCVD) apparatus.

13. The apparatus of claim 12, wherein the first source gas is a gas flowing into the process chamber at a room temperature, and the second source gas is a metal organic gas inflowing into the process chamber in a heated state.

14. The apparatus of claim 1, wherein the heating device is a heater installed on the first supply pipe.

15. The apparatus of claim 11, wherein the shower part comprises:
a first inlet part which the first source gas flows into;
a second inlet part which the second source gas flows into, wherein the second inlet part is separated from the first inlet part.

16. The apparatus of claim 1, wherein a layer deposited is a ferroelectric layer.

17. The apparatus of claim 11, wherein the first source gas is an oxygen gas, and a second source gas includes lead (Pb) or compounds thereof, zirconium (Zr) or compounds thereof and titanium (Ti) or compounds thereof.

18. A heating arrangement for heating a source gas in an apparatus for fabricating a semiconductor device, comprising:
at least one heating device for heating at least one source gas input to the apparatus for fabricating the semiconductor device.

19. The heating arrangement of claim 18, wherein the at least one heating device is placed in a path of a pipe for delivering the at least one source gas to the apparatus for fabricating the semiconductor device.

20. The heating arrangement of claim 18, the at least one heating device including a heat pipe including at least one part.

21. The heating arrangement of claim 20, wherein the at least one part is embedded in or inside a wall of a process chamber of the apparatus for fabricating the semiconductor device.

22. The heating arrangement of claim 20, further comprising a liner adjacent to the at least one part.

23. The heating arrangement of claim 20, wherein the at least one part is a two-dimensional or three-dimensional shape.

24. The heating arrangement of claim 23, wherein the at least one part is a linear, spiral, or helical shape.

25. The heating arrangement of claim 20, the heat pipe including at least two parts.

26. The heating arrangement of claim 25, wherein the at least two parts are a two-dimensional or three-dimensional shape.

27. The heating arrangement of claim 26, wherein the at least two parts are a linear, spiral, or helical shape.

28. The heating arrangement of claim 20, the heat pipe including at least three parts.

29. The heating arrangement of claim 28, wherein the at least three parts are a two-dimensional or three-dimensional shape.

30. The heating arrangement of claim 29, wherein the at least three parts are a linear, spiral, or helical shape.

31. A method of reducing thermal disturbance during fabrication of a semiconductor device, comprising:
heating a first source gas to be supplied to a process chamber above room temperature; and
heating all other source gases to be supplied to the process chamber above room temperature.

32. A method of exchanging heat during fabrication of a semiconductor device, comprising:
heating a source gas to be supplied to a process chamber above room temperature using a heat source internal to the process chamber.

33. The method of claim 32, wherein the heat source internal to the process chamber is a heat source for a susceptor in the process chamber.
